(19) United States
(12) Patent Application Publication
(10) Pub. No.: US 2009/0188790 A1
(43) Pub. Date: Jul. 30, 2009

(54) CONCENTRIC HOLLOW CATHODE MAGNETRON SPUTTER SOURCE

(75) Inventors: DANIEL BRORS, DISCOVERY BAY, CA (US); Dominik Schmidt, San Francisco, CA (US); Michael Hawran, Milpitas, CA (US); Dave Correia, Fremont, CA (US); Art Shulenberger, Milbrae, CA (US)

Correspondence Address: SAWYER LAW GROUP LLP, 2465 E. Bayshore Road, Suite No. 406, PALO ALTO, CA, 94303, US

(73) Assignee: 4D-S Pty. Ltd., PERTH (AU)

(21) Appl. No.: 12/355,603

(22) Filed: Jan. 16, 2009

Related U.S. Application Data
(60) Provisional application No. 61/022,043, filed on Jan. 18, 2008.

(51) Int. Cl. C23C 14/35

(52) U.S. Cl. 204/298.16

(57) ABSTRACT

A new sputter source is disclosed that allows for high rates of deposition at pressures one or two orders of magnitude lower than has previously been obtained. This results in denser films with reduced ion and electron damage to the substrate.

### FIELD OF THE INVENTION

The present invention relates generally to a sputter source and more specifically to a magnetron sputter source, the deposition of materials and more specifically to utilizing a sputter source for the deposition of the material.

### BACKGROUND OF THE INVENTION

The deposition of materials using a magnetron enhanced sputter source has been used for more than 30 years. The cross section of a typical circular magnetron sputter source is shown in FIG. 1. The sputter source 100 is placed in a vacuum chamber 101. The vacuum chamber 101 is attached to a vacuum pump (not shown) through a port 109. Magnets 106 are arranged in 2 concentric rings and attached to an iron yoke 107 resulting in a strong magnetic field 104 that penetrates the target 108 and is largely parallel 110 with the target surface 109. The strong magnetic field 110, typically >300 gauss, parallel to the target surface 109 traps the gas ions near the target surface 109 resulting in an increase of several orders of magnitude if ions available for sputtering which results in a corresponding increase in the sputtering rate. A power supply (not shown) DC or RF is electrically attached from the chamber 101 to the target 108. A gas, typically argon, is metered into the vacuum chamber 101 through a MFC 111 to pressure of typically 3×10E−3 to 1×10E− Torr. The power supply is turned on and the voltage is raised to 300-400 volts for a DC power supply and typically 1-10 KW for an RF supply resulting in sputtering of the target surface 109. The target material 108 is deposited onto the substrate 105 which is held in place by a chuck 03, which is typically temperature controlled. Such an arrangement results in a 10 to 100 fold increase in the deposition rate of material from the target 108 onto the substrate surface 105 when compared to sputtering without magnets 106.

Various other magnetic arrangements have been used for sputtering, all based on a magnetic field penetrating the surface of a target and a magnetic field parallel to the target surface. An example is shown in FIG. 2 and is known a hollow cathode 200. The hollow cathode 200 is placed in a vacuum chamber 201 which is attached to a vacuum pump (not shown) and has a gas injection port 110 the same as in FIG. 1. The hollow cathode 200 is placed in a vacuum chamber 201 which is attached to a vacuum pump (not shown) and has a gas injection port 110 the same as in FIG. 1. The hollow cathode 200 consists of cylindrical housing 202. Two rings of magnets 206 are attached to an iron yoke 207 resulting in a strong magnetic field 204 that penetrates the target 208. A DC or RF power supply (not shown) 3 is attached from the vacuum chamber 201 to the target 208 as was done in FIG. 1. Argon is introduced into the vacuum chamber 201 through port 101 and typically metered by a MFC 111 to a pressure of 3-10×10E−3 Torr. The power supply is turned on to 300-400 volts for a DC supply and typically 1 -10 KW for an RF supply. Sputtering occurs where the magnetic field 210 is largely parallel to the target surface 209. The deposition rate onto the substrate surface is many times greater than the deposition rate without magnets. The hollow cathode 200 results in directional sputtering and is used for sputtering onto substrates with features with aspect ratios, i.e. >5:1.

Accordingly what is needed is a system and method that allows for high rates of deposition at low pressures. The present invention addresses such a need.

### SUMMARY OF THE INVENTION

A new sputter source is disclosed that allows for high rates of deposition at pressures one or two orders of magnitude lower than has previously been obtained. This results in denser films with reduced ion and electron damage to the substrate.

### BRIEF DESCRIPTION OF DRAWINGS

FIG. 1 shows an example of a cross section of a typical circular magnetron sputter source.

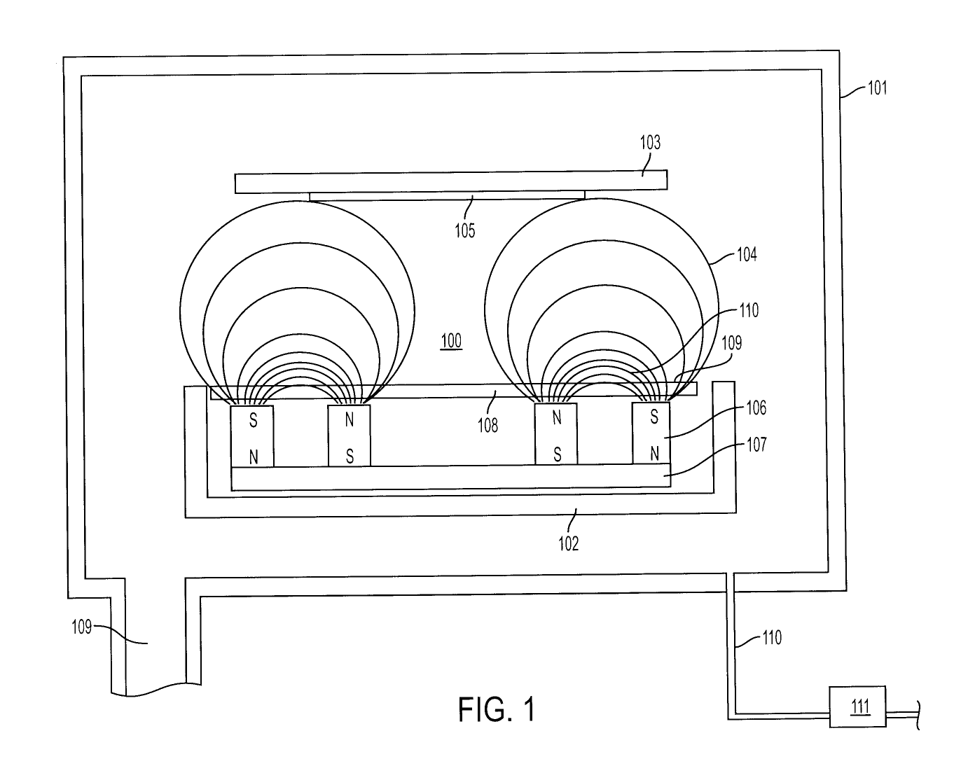

FIG. 2 shows an example of prior art which is known as a hollow cathode.

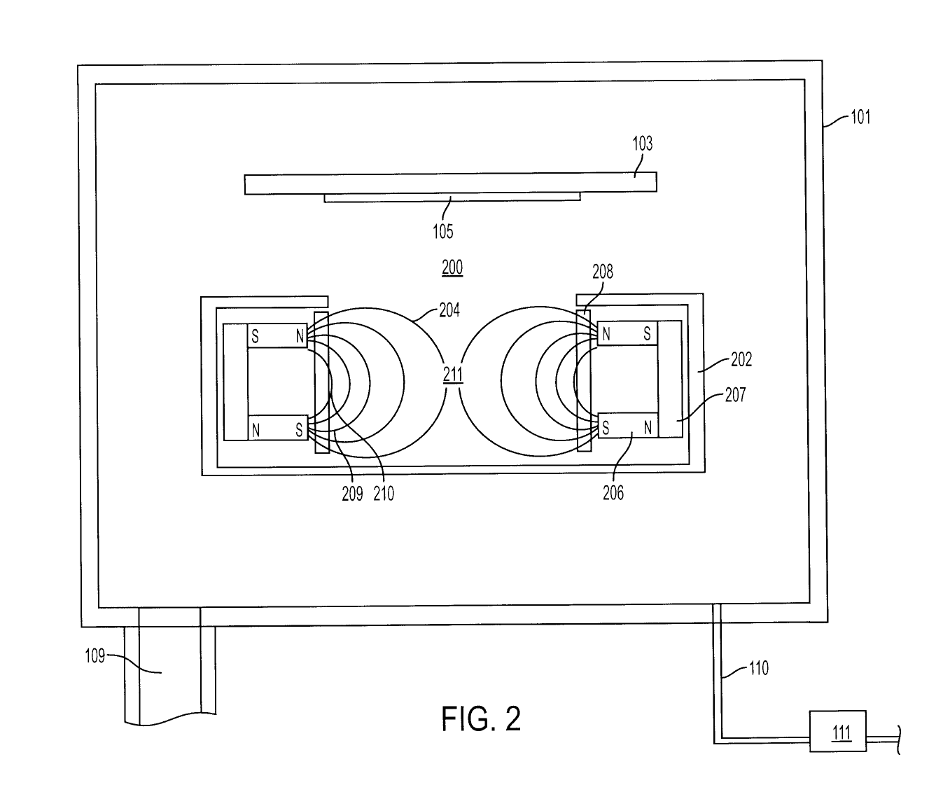

FIG. 3 shows the present invention, a cross section of the sputter source which consists of a circular housing.

FIG. 4 is a top view of the present invention and shows the inner ring of magnets and outer ring of magnets arranged in a hexagon.

### DETAILED DESCRIPTION OF PREFERRED EMBODIMENTS

The present invention relates generally to a sputter source and more specifically to a magnetron sputter source, the deposition of materials and more specifically to utilizing a sputter source for the deposition of the material. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

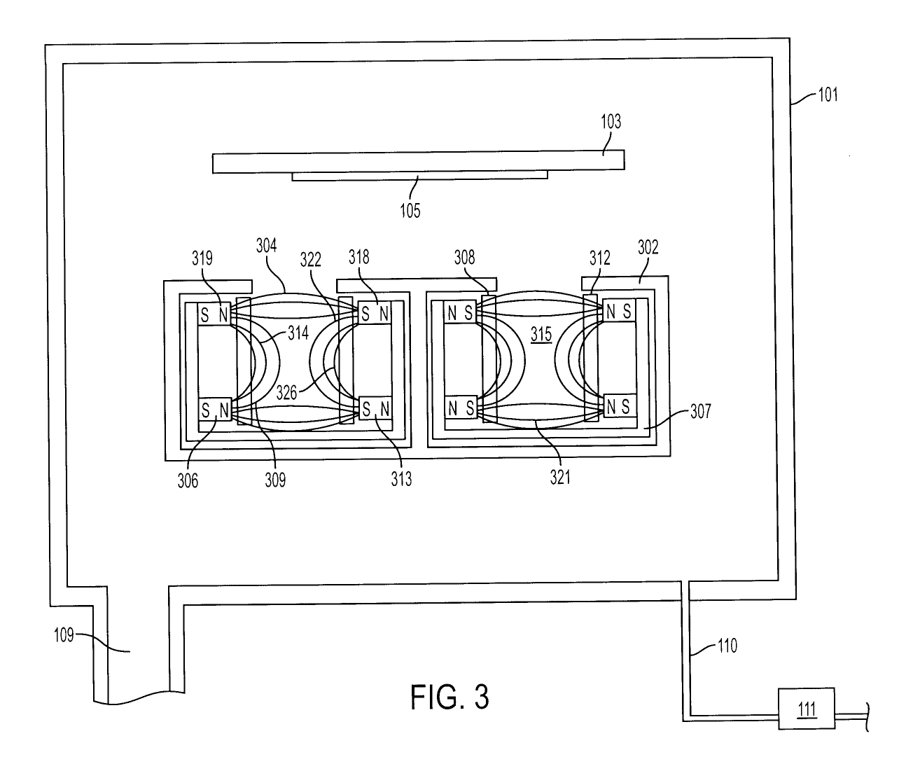

The present invention is a “Concentric Hollow Cathode Sputter Source” and is shown in FIG. 3. FIG. 3 is a cross section of the sputter source 300 which consists of a circular housing 302. A outer hexagon ring of two rows of magnets 306, 319 are attached to an iron yoke 302 and an inner hexagonal ring of two rows of magnets 306, 319 are attached to an iron yoke 302 and an inner hexagonal ring of two rows of magnets 313, 318 are also attached to iron yoke 302. The iron yoke 302 is the return path for the magnetic flux from all the magnets.

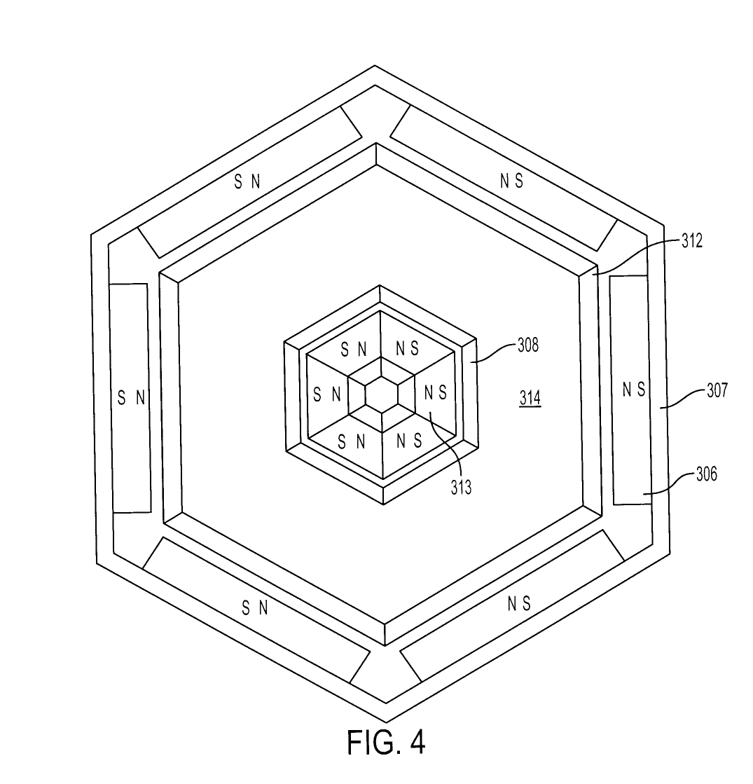

FIG. 4 is a top view of the present invention and shows the inner ring of magnets 313 and outer ring of magnets 306 arranged in a hexagon. Other configurations are possible such as 3 sides, 4 sides, etc., however 6 sides is the preferred configuration. All the magnets are attached to the iron yoke 307.

Referring to FIG. 3, the magnetic field has three components. The first component is a magnetic field 314 from the upper row of outer magnets 319 to the lower row of outer magnets 306 that penetrates the outer row of targets 312 and is largely parallel to the outer target surface 309 which traps ions near the surface 309 and results in a high rate of sputtering from the outer target surfaces 312. A second magnetic field 316 is generated from the inner row of upper magnets 318 to the inner row of low magnets 313 which penetrates the inner targets 308 and is largely parallel to the inner target surface 322 and traps ions at the inner target surface 322 and results in a high rate of sputtering from the inner target surfaces 322. The third magnetic field 304 is generated from the outer ring of upper magnets 319 to the inner ring of magnets 318. A similar magnetic field 321 is generated at the bottom of the cavity 315 between the outer ring of lower magnets 306 and the inner ring of lower magnets 313. Magnetic fields 304 and 321 trap ions and electrons within the cavity 315 which results in increasing the ion density within the cavity 315 and allows sputtering at pressures of 2×10E−5 to 1×10E−2 Torr and preferably at 5×10E−5 to 5×E−4 Torr. Other magnetron sputter sources such as the planar source 100 and the hollow cathode 200 require pressures from 3×10E−3 to 1×10E−2 Torr. The low pressure of this concentric hollow source 300 results in denser sputtered films with less argon or any other gases used in the sputtering process trapped in the deposited film. The lower pressure also increases the mean free path in the vacuum reducing the collusions between the gas molecules and the sputtered material resulting in an increase in the average energy of the arriving sputtered material at the substrate surface, which also increases the deposited material density. A second advantage of trapping the ions and electrons within the cavity 315 is that the number of ions and electrons reaching the substrate surface 105 is greatly reduced as compared to the planar source 100 or the hollow cathode 200. The reduced ions and electrons reaching the substrate surface 105 greatly reduces ion and electron damage to semiconductor devices fabricated on the substrate surface 105.

Although the present invention has been described in accordance with the embodiments shown, one of ordinary skill in the art will readily recognize that there could be variations to the embodiments and those variations would be within the spirit and scope of the present invention. For example, although the splice is preferably made of a conductive material such as aluminum, it could be made utilizing a non-conductive material which has a conductive capability added to its surface and its use would be within the spirit and scope of the present invention. Accordingly, many modifications may be made by one of ordinary skill in the art without departing from the spirit and scope of the appended claims.

What is claimed is:

1. A concentric sputter source within a vacuum chamber, the concentric sputter source comprising of two rows of magnets in an outer ring and two rows of magnets in an inner ring.

2. The concentric sputter source of claim 1, wherein the two rows of magnets on the outer ring and the two rows of magnets on the inner ring are arranged so that the magnetic poles on the upper ring attracting the inner upper ring of magnets and are also attracting the outer ring of magnets and the inner lower ring of magnets is attracting the outer lower ring of magnets.

3. The concentric sputter source of claim 1, wherein the outer ring magnets are attached to a first iron yoke which is a return path on the magnetic fields; and
the inner ring magnets are attached to a second iron yoke which is a return path on the magnetic fields.

4. The concentric sputter source of claim 1, wherein the inner and outer magnet rings consists of 3 sides or more sides.

5. The concentric sputter source of claim 1, wherein the inner and outer magnet rings preferably consist of 6 sides.

6. The concentric sputter source of claim 1, wherein the magnetic field at a target surfaces is 200-1000 gauss.

7. The concentric sputter source of claim 1, wherein the magnetic field at the target surfaces is preferably 300-400 gauss.

8. The concentric sputter source of claim 1, wherein the magnetic field from the outer magnet ring to the inner magnet ring is 300-1000 gauss.

9. The concentric sputter source of claim 1, wherein the magnetic field from the outer magnetic ring to the inner magnetic ring is preferably 300-400 gauss.

10. The concentric sputter source of claim 1, wherein the vacuum chamber operates at pressures as low as 2×10E−5 Torr.
